(19) United States
(12) Patent Application Publication
(10) Pub. No.: US 2014/0291002 A1
(43) Pub. Date: Oct. 2, 2014

(54) PRINTED CIRCUIT BOARD MODULE

(71) Applicant: HON HAI PRECISION INDUSTRY CO., LTD., New Taipei (TW)

(72) Inventors: PO-YUAN LIN, New Taipei (TW); LI-DONG TANG, Kunshan (CN); CHIH-HAO LEE, New Taipei (TW)

(73) Assignee: HON HAI PRECISION INDUSTRY CO., LTD., New Taipei (TW)

(21) Appl. No.: 14/228,280

(22) Filed: Mar. 28, 2014

(30) Foreign Application Priority Data
Mar. 28, 2013 (CN) 2013201470908

(51) Int. Cl. H05K 1/11

(52) U.S. Cl. CPC H05K 1/11
USPC 174/261

(57) ABSTRACT

A printed circuit board module includes a first printed circuit board defining a plurality of front conductive pads formed on a top surface thereof and arranged along a transversal direction, and a second printed circuit board located on and welded to the first printed circuit board, the second printed board defining a plurality of first contacts formed on a top surface thereof for mating with a complementary connector.

### BACKGROUND OF THE INVENTION

1. Field of the Invention

The present invention relates to a printed circuit board module, more particularly to a printed circuit board module formed in an electrical connector for signal transmission.

2. Description of Related Art

In existing technology, the contact accommodated in the electrical connector is designed to meet a certain thickness due to a requirement of the whole structure of the electrical connector. To meet a thickness requirement of the contact, the contact can be cut to side in a stamping or similar process from a metallic shell. Whereas, two aforementioned manufacturing processes of the contact both need a large amount of copper, and not cost-effective. Meanwhile, the contact itself has great impedance value due to a certain thickness result in weak signal transmission through the contact. Thus, the contact cannot satisfy the requirement of signal transmission.

Hence, an improved printed circuit board module is highly desired to overcome the disadvantages of the present invention.

### BRIEF SUMMARY OF THE INVENTION

Accordingly, an object of the present invention is to provide a printed circuit board module having a simple and easily manufacturing process.

In order to achieve the above-mentioned object, a printed circuit board module in accordance with the present invention comprises: a first printed circuit board defining a plurality of front conductive pads formed on a top surface thereof and arranged along a transversal direction, and a second printed circuit board located on and welded to the first printed circuit board, the second printed board defining a plurality of first contacts formed on a top surface thereof for mating with a complementary connector.

Other objects, advantages and novel features of the invention will become more apparent from the following detailed description when taken in conjunction with the accompanying drawings.

### BRIEF DESCRIPTION OF THE DRAWINGS

FIG. 1 is an assembled, perspective view of a printed circuit board module in accordance with the present invention;

FIG. 2 is similar to FIG. 1, but viewed from another aspect;

FIG. 3 is an exploded, perspective view of FIG. 1;

FIG. 4 is an exploded, perspective view of FIG. 2; and

FIG. 5 is a cross-section view of the printed circuit board module of FIG. 1 assembled with an insulative housing and a metallic shell taken along line 5-5.

### DETAILED DESCRIPTION OF THE PREFERRED EMBODIMENTS

Reference will now be made in detail to the preferred embodiment of the present invention.

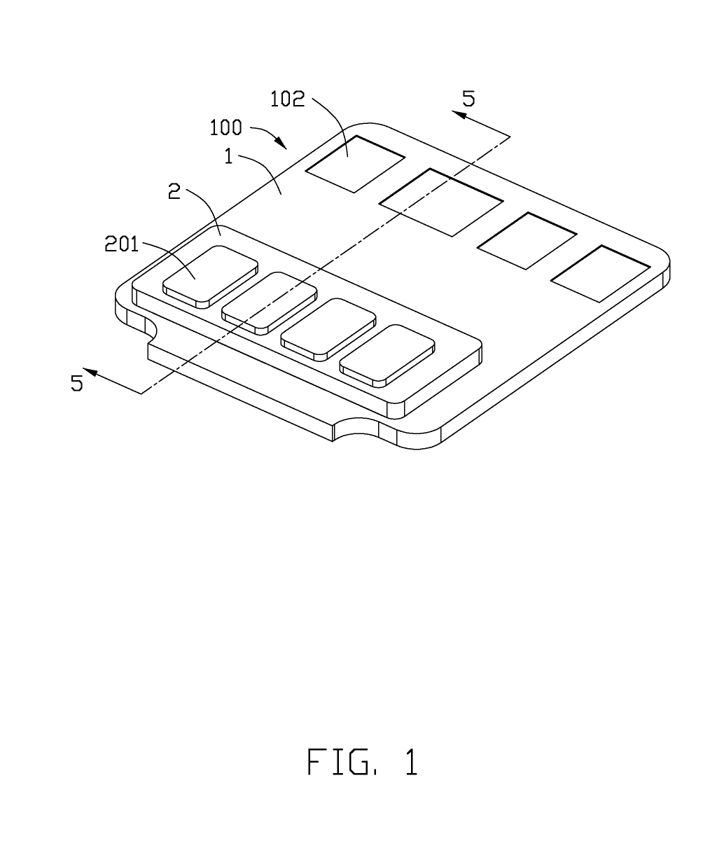

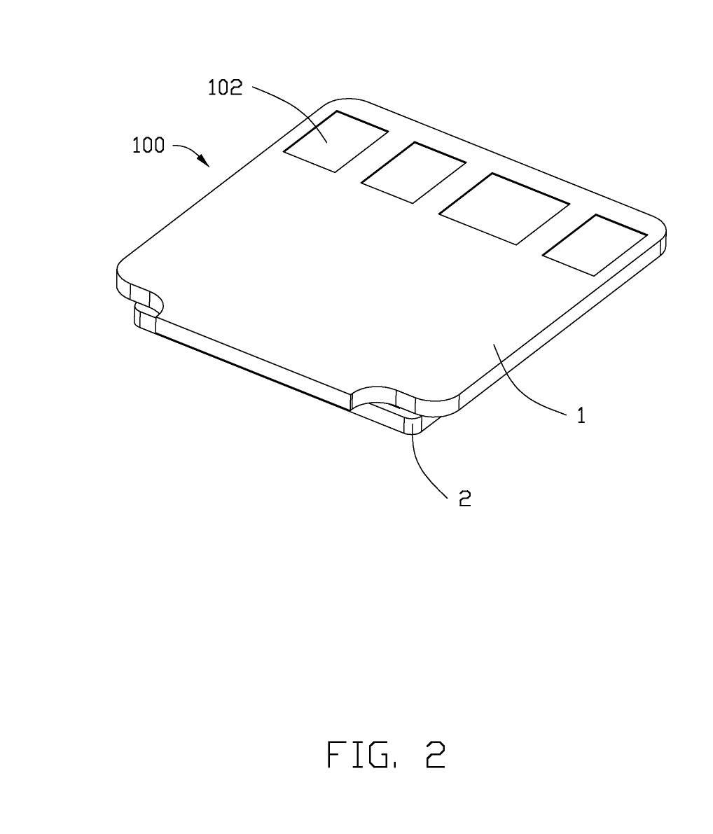

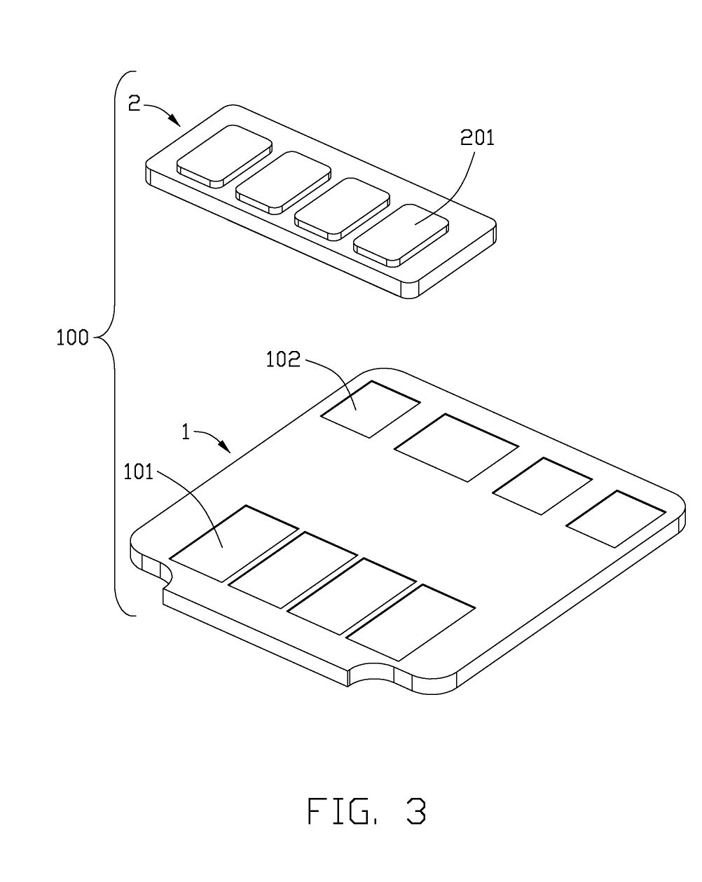

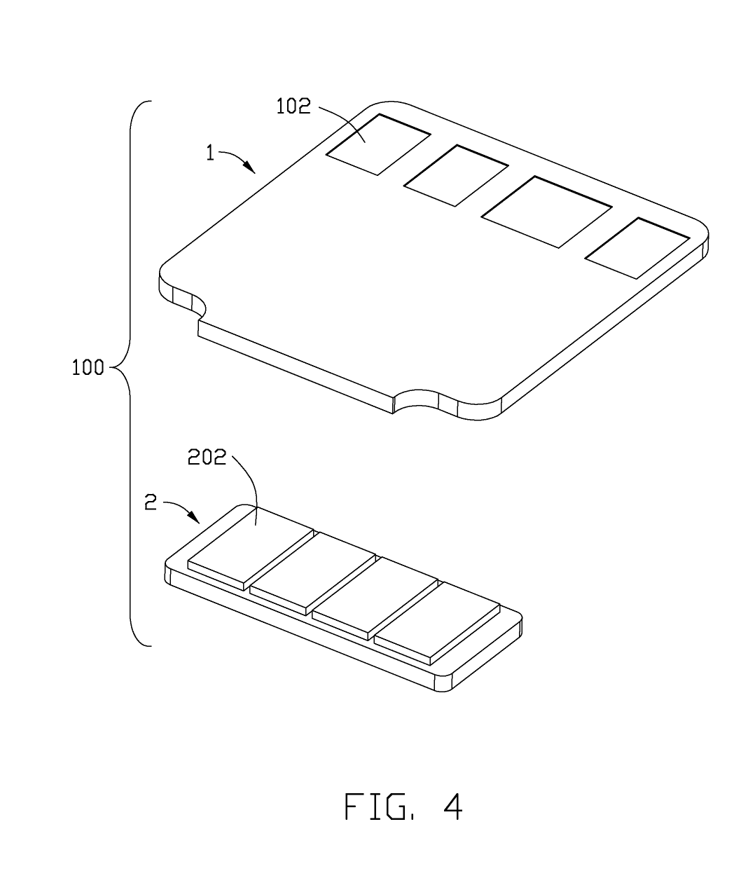

Referring to FIGS. 1-5, a printed circuit board module 100 in accordance with the present invention comprises a first printed circuit board 1 and a second printed circuit board 2 welded on the first printed circuit board 1. A thickness of the second printed circuit board 2 is larger than a thickness of the first printed circuit board 1. And a size of the second printed circuit board 2 is smaller than a size of the first printed circuit board 1. The second printed circuit board 2 is used to mate with a complementary connector.

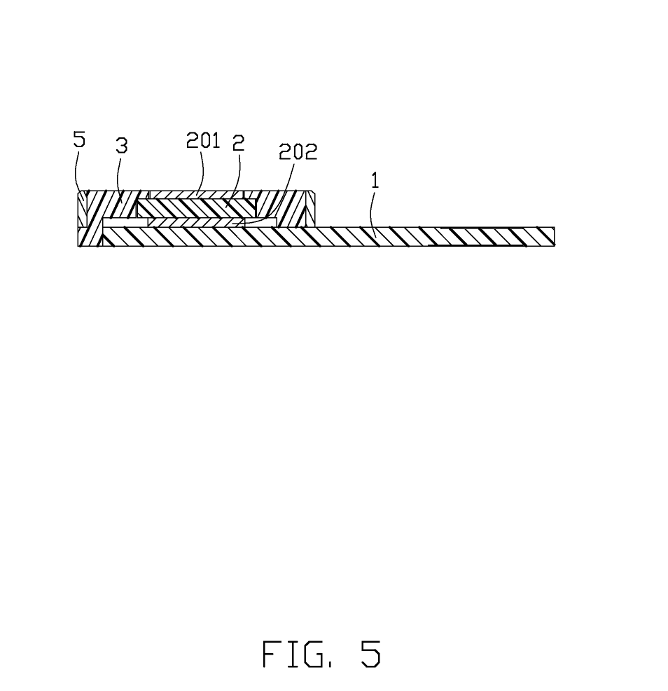

Referring to FIG. 5, the printed circuit board module 100 further comprises an insulative housing 3 and a metallic shell 5. The first printed circuit board 1 and the second printed circuit board 2 are together assembled to the metallic shell 5. The insulative housing 3 is formed between the metallic shell 5 and the first and second printed circuit boards 1, 2 by inserting molding process.

Referring to FIGS. 1-4, the first printed circuit board 1 defines a plurality of front conductive pads 101 arranged on a top surface of a front end thereof along a transversal direction and a plurality of rear conductive pads 102 arranged on a top surface of a rear end thereof along a transversal direction. The front conductive pads 101 are welded to the second printed circuit board 2. The rear conductive pads 102 are used to weld to a cable.

Referring to FIGS. 1-5, the first printed circuit board 2 defines a plurality of first contacts 201 and second contacts 202 respectively formed on top and bottom surface thereof The plurality of first and second contacts 201, 202 respectively protrude outwardly from top and bottom surfaces for a distance. The first contacts 201 and the second contacts 202 are electrically connected. Each of first contact 201 has a top mating surface. And the top mating surfaces of the plurality of first contacts 201 are considered as mating face of the printed circuit board module 100 for mating with a plurality of contacts (not shown) accommodated in the complementary connector. The plurality of second contacts 202 are welded to the plurality of corresponding front conductive pads 101 of the first printed circuit board 1. The plurality of first contacts 201 and the second contacts 202 are structured in a flat shape. Each of second contact 202 has a length longer than a length of the first contact 201. The plurality of first contacts 201, the insulative housing 3 and the metallic shell 5 are in the same plane.

The manufacturing process of the printed circuit board module 100 made in according to the present invention comprises following manufacturing steps.

Firstly, providing a first printed circuit board 1 and a second printed circuit board 2. The first printed circuit board 1 defines a plurality of front conductive pads 101. The second printed circuit board 2 define a plurality of second contacts 202 formed on a bottom surface thereof and extending downwardly from the bottom surface for a distance.

Secondly, applying a plurality of solders on the corresponding front conductive pads 101 of the first printed circuit board 1.

Thirdly, applying the second printed circuit board 2 on the first printed circuit board 1. The plurality of second contacts 202 are respectively located on the corresponding solder formed on the front conductive pad 101.

Fourthly, welding the front conductive pads 101 of the first printed circuit board 1 to the second contacts 202 of the second printed circuit board 2 through hot-bar or (SMT)surface mount technology process.

There are two forming methods of forming the first contacts 201 and the second contacts 202 of the second printed circuit board 2. And, the aforementioned two forming methods are detailed described as follow.

Firstly, the first contacts 201 and the second contacts 202 are respectively formed on the top and bottom surfaces of the second printed circuit board 2 through hot-bar or SMT(surface mount technology) process.

Secondly, the first contacts 201 and the second contacts 202 are respectively formed on the top and bottom surfaces of the second printed circuit board through a gold removing method to remove the needless material of the second printed circuit board 2.

A printed circuit board module in accordance with another embodiment of the present invention further comprises optionally a third printed circuit board formed on a bottom surface of the first printed circuit board in a symmetrical manner with regard to the second printed circuit board 2 wherein the housing 3 and the shell 5 are also unitarily applied upon the additional third printed circuit board. Yet another embodiment discloses the contacts 201 and 202 are attached to the corresponding printed circuit board through hot-bar or SMT (surface mounting technology) process.

It should be noted that a thickness of first and second contacts 201, 202 of the second printed circuit board is thin. Thus, impedance value of the first and second contacts 201, 202 is lower. So, signal through the first and second contacts 201, 202 of present invention is strong to meet a signal transmission requirement of the terminal

It will be understood that the invention may be embodied in other specific forms without departing from the spirit or central characteristics thereof The present examples and embodiments, therefore, are to be considered in all respects as illustrative and not restrictive, and the invention is not to be limited to the details given herein.

What is claimed is:

1. A printed circuit board module, comprising:
a first printed circuit board defining a plurality of front conductive pads formed on a top surface thereof and arranged along a transversal direction; and
a second printed circuit board located on and welded to the first printed circuit board, the second printed board defining a plurality of first contacts formed on a top surface thereof for mating with a complementary connector.

2. The printed circuit board module as claimed in claim 1, wherein the second printed circuit board defines a plurality of second contacts formed on a bottom surface thereof and electrically connected with the plurality of front conductive pads.

3. The printed circuit board module as claimed in claim 2, wherein the first and second contacts respectively protrudes from the top and bottom surfaces for a distance.

4. The printed circuit board module as claimed in claim 1, wherein the first printed circuit board further defines a plurality of rear conductive pads arranged on a rear end thereof along a transversal direction.

5. The printed circuit board module as claimed in claim 1, wherein a thickness of the second printed circuit board is larger than a thickness of the first printed circuit board.

6. The printed circuit board module as claimed in claim 2, wherein the plurality of front conductive pads of the first printed circuit board are electrically connected to the second contacts of the second printed circuit board through hot-bar or SMT(surface mount technology) process.

7. The printed circuit board module as claimed in claim 1, wherein a size of the second printed circuit board is smaller than a size of the first printed circuit board.

8. The printed circuit board module as claimed in claim 1, wherein top surface of the first contacts of the second printed circuit board is a mating surface of the printed circuit board.

9. The printed circuit board module as claimed in claim 2, wherein a length of the second contact is longer than a length of the first contact.

10. The printed circuit board module as claimed in claim 1, wherein the printed circuit board module further comprises a metallic shell surrounding the first and second printed circuit boards and an insulative housing formed between the metallic shell and the first and second printed circuit boards through inserting-molding process.

11. The printed circuit board module as claimed in claim 10, wherein top surface of the second contact is flushed with top surfaces of the metallic shell and the insulative housing.

12. A printed circuit board assembly comprising:
a main printed circuit board defining opposite first and second surfaces thereon;
a secondary printed circuit board dimensioned smaller than and positioned upon the first surface of the main printed circuit board and defining opposite first and second faces wherein the second face intimately contacts the first surface of the main printed circuit board;
a first conductor formed on the first face; and
a second conductor formed on the second face and hidden between the main printed circuit board and the secondary printed circuit board; wherein
the first conductor and the second conductor are electrically connected to each other via circuits formed in the secondary printed circuit board.

13. The printed circuit board assembly as claimed in claim 12, wherein an insulative housing is applied upon the secondary printed circuit board while exposing the first conductor to an exterior.

14. The printed circuit board assembly as claimed in claim 13, wherein a metallic shell is further applied upon the housing while exposing the first conductor.

15. The printed circuit board assembly as claimed in claim 13, wherein the housing is further applied upon the main printed circuit board partially.

16. The printed circuit board assembly as claimed in claim 15, wherein a front edge of the main printed circuit board is covered by the housing.

17. The printed circuit board assembly as claimed in claim 12, further including an additional secondary printed circuit board mounted upon the second surface of the main printed circuit board and symmetrically arranged with regard to said secondary printed circuit board so as to allow the whole printed circuit board assembly can be mated with a complementary component in a flippable manner.
